(19) United States
(12) Patent Application Publication
(10) Pub. No.: US 2010/0279460 A1
(43) Pub. Date: Nov. 4, 2010

(54) ORGANIC THIN FILM TRANSISTOR

(76) Inventors: Takumi Yamaga, Yokohama-shi (JP); Toshiya Sagisaka, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/836,619

(22) Filed: Jul. 15, 2010

Related U.S. Application Data
(62) Division of application No. 11/816,437, filed on Aug. 16, 2007.

(30) Foreign Application Priority Data
Feb. 17, 2005 (JP) 2005-040352

(51) Int. Cl. H01L 51/40

(52) U.S. Cl. 438/99; 257/E51.006

(57) ABSTRACT

To provide an organic thin film transistor including a pair of electrodes for allowing a current to flow through an organic semiconductor layer made of an organic semiconductor material, and a third electrode, wherein the organic semiconductor material is composed mainly of an arylamine polymer having a weight-average molecular weight (Mw) of 20,000 or more.

### REFERENCE TO RELATED APPLICATIONS

The present application is a Divisional application of U.S. application Ser. No. 11/816,437, filed Aug. 16, 2007, pending, the entire contents of which are hereby incorporated by reference.

### TECHNICAL FIELD

The present invention relates to an organic thin film transistor which is used as a switching device for various types of displays including liquid crystal displays, electrophoretic displays and organic EL displays and which has an organic semiconductor layer containing triarylamine-based polymers.

### BACKGROUND ART

In recent years, thin film transistors that have an organic semiconductor material as an active layer have been receiving widespread attention as inexpensive alternatives for silicon-based thin film transistors. Constructing devices by use of organic materials can achieve easy formation of thin films or circuits through a wet process such as printing, spin coating, or dipping. Specifically, it is possible to manufacture devices without involving costly steps that are required in the manufacturing process for silicon-based thin film transistors, with a significant reduction in the manufacturing costs and increase in the device area being expected.

The advantages of organic material-based devices include their mechanical flexibility and lightness. Although inorganic materials have better performance than organic materials in terms of carrier mobility, organic semiconductor devices have been receiving widespread attention because they have such advantages.

Examples of the disclosed semiconductor materials used for such organic thin film transistors include as low-molecular materials pentacene (see Non-Patent Literature 1), phthalocyanine (see Non-Patent Literature 2), fullerene (see Patent Literature 1 and Non-Patent Literature 3), anthradithiophene (see Patent Literature 2), thiophene oligomers (see Patent Literature 3 and Non-Patent Literature 4) and bisdithienothiophene (see Non-Patent Literature 5); and as high-molecular materials polythiophene (see Non-Patent Literature 6) and polythenylenevinylene (see Non-Patent Literature 7).

These materials have fascinating carrier mobility as an organic semiconductor for thin film transistor devices. These materials, however, require several improvements before they are applied to commercial thin film transistor devices using an organic semiconductor. For example, although it is reported that pentacene has a carrier mobility of as high as 1 cm²/Vs, pentacene has low solubility in solvents, and it is therefore difficult to obtain a pentacene active layer by dissolving it in a solvent and applying the resultant solution. Moreover, pentacene is susceptible to oxidization—it tends to become oxidized with time under oxygen atmosphere. Similarly, phthalocyanine and fullerene have, for example, low solubility in solvents, and therefore semiconductor layers generally need to be formed by vapor deposition. For these reasons, these materials cannot achieve the cost reduction of the manufacturing process, increase in the device area, etc., which are the distinctive characteristics of organic material-based devices. In addition, these materials have the following problems: films may fall off a substrate because of deformation of the substrate, which may cause cracks or the like on the films.

Furthermore, polyalkylthiophene-based materials have received attention as materials which can be formed into an active layer by dissolving them in solvents and applying the resultant solutions, and which have relatively high mobility (see Non-Patent Literature 6). These polyalkylthiophene-based materials, however, have the following defects: they cause a reduction in the on/off ratios of devices, and they are susceptible to oxidization and thus their characteristics vary with time.

Although several materials have been proposed as organic semiconductor materials used for thin film transistors as described above, no organic semiconductor material that satisfies all required characteristics has yet been provided. Preferred organic semiconductor materials are required to show excellent transistor characteristics, to be capable of being dissolved in such solvents that allow formation of excellent thin films through a wet process, and to have stability, e.g., resistance to oxidization.

In light of this circumstance, the present applicant proposed a new material made of an arylamine polymer (see Patent Literature 4). Meanwhile, Patent Literature 5 discloses that different alkylthiophene-based high-molecular organic semiconductor materials show different characteristics because of the differences in their weight-average molecular weight (Mw). One reason why their characteristics are improved owing to an increase in the molecular weight may be as follows: the likelihood that the molecular chains are overlapped on top each other is increased, thereby allowing electrons to easily hop from one molecular chain to another. However, organic semiconductor materials with high molecular weights may have a problem of reduction in their solubility, for example.

In order to drive liquid crystal displays, electrophoretic displays or organic EL displays, organic thin film transistors are technically required to have a field effect mobility of 1×10⁻⁴ cm²/Vs or more, depending on the display resolution and display area.

[Patent Literature 1] Japanese Patent Application Laid-Open (JP-A) No. 08-228034

[Patent Literature 2] Japanese Patent Application Laid-Open (JP-A) No. 11-195790

[Patent Literature 3] Japanese Patent (JP-B) No. 3145294

[Patent Literature 4] Japanese Patent Application Laid-Open (JP-A) No. 2005-240001

[Patent Literature 5] Japanese Patent Application Laid-Open (JP-A) No. 06-177380

[Non-Patent Literature 1] Synth. Met., 51, 419, 1992

[Non-Patent Literature 2] Appl. Phys. Lett., 69, 3066, 1996

[Non-Patent Literature 3] Appl. Phys. Lett., 67, 121, 1995

[Non-Patent Literature 4] Chem. Mater., 4, 457, 1998

[Non-Patent Literature 5] Appl. Phys. Lett., 71, 3871, 1997

[Non-Patent Literature 6] Appl. Phys. Lett., 69, 4108, 1996

[Non-Patent Literature 7] Appl. Phys. Lett., 63, 1372, 1993

### DISCLOSURE OF INVENTION

It is an object of the present invention to provide an organic thin film transistor with high field effect mobility by optimizing the molecular weight of the polymer constituting the semiconductor material that can be formed into a film by dissolving it in a solvent and applying the resultant solution. With such an organic thin film transistor it is possible to manufacture large-area devices at low costs by an easy-to-use process such as printing or inkjet (IJ).

The present inventors have diligently conducted studies to achieve the foregoing objects. As a result, they have established that a polymer with a specific structure is effective in achieving these objects and that such a polymer can be imparted with high carrier mobility by optimizing its molecular weight.

The following items are the means for solving the foregoing problems.

(1) An organic thin film transistor including: a pair of electrodes for allowing a current to flow through an organic semiconductor layer made of an organic semiconductor material, and a third electrode, wherein the organic semiconductor material contains a polymer having a repeating unit expressed by the following general structural formula (I), and the polymer has a weight-average molecular weight (Mw) of 20,000 or more,

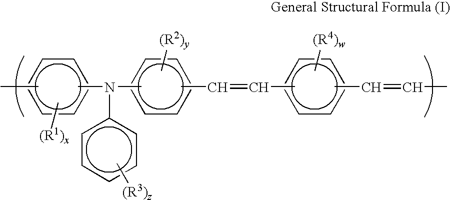

where R¹, R² and R⁴ each independently represents a halogen atom or a group selected from an alkyl group, alkoxy group and alkylthio group all of which may be substituted, R³ represents a halogen atom or a group selected from an alkyl group, alkoxy group, alkylthio group and aryl group all of which may be substituted, z represents an integer of 0 to 5, x, y and w each independently represents an integer of 0 to 4, and when two or more of each of R¹, R², R³ and R⁴ appear, the R's may be the same or different.

(2) The organic thin film transistor according to (1), wherein the polymer has a weight-average molecular weight of 25,000 or more.

(3) The organic thin film transistor according to one of (1) and (2), wherein R⁴ in the general structural formula (I) represents one of an alkyl group and an alkoxy group.

(4) The organic thin film transistor according to any one of (1) to (3), wherein the organic semiconductor material contains a polymer having a repeating unit expressed by the following general structural formula (II):

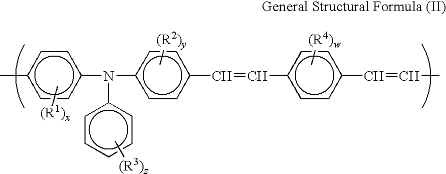

where R¹, R² and R⁴ each independently represents a halogen atom or a group selected from an alkyl group, alkoxy group and alkylthio group all of which may be substituted, R³ represents a halogen atom or a group selected from an alkyl group, alkoxy group, alkylthio group and aryl group all of which may be substituted, z represents an integer of 0 to 5, x, y and w each independently represents an integer of 0 to 4, and when two or more of each of R¹, R², R³ and R⁴ appear, the R's may be the same or different.

(5) The organic thin film transistor according to any one of (1) to (4), wherein the organic semiconductor material contains a polymer having a repeating unit expressed by the following general structural formula (III):

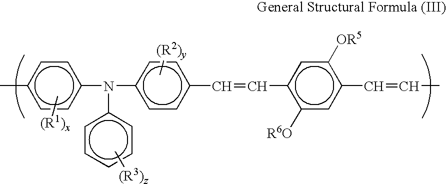

where R¹ and R² each independently represents a halogen atom or a group selected from an alkyl group, alkoxy group and alkylthio group all of which may be substituted, R³ represents a halogen atom or a group selected from an alkyl group, alkoxy group, alkylthio group and aryl group all of which may be substituted, R⁵ and R⁶ represent a straight or branched alkyl group which may be substituted, z represents an integer of 0 to 5, x and y each independently represents an integer of 0 to 4, and when two or more of each of R¹, R² and R³ appear, the R's may be the same or different.

(6) The organic thin film transistor according to any one of (1) to (5), wherein the organic semiconductor material contains a repeating unit expressed by the following structural formula.

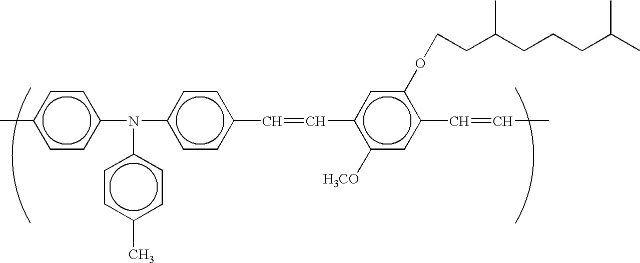

(7) The organic thin film transistor according to any one of (1) to (6), wherein the third electrode is a gate electrode, and an insulating layer is provided between the gate electrode and the organic semiconductor layer.

### BRIEF DESCRIPTION OF DRAWINGS

FIG. 1A is a schematic cross-sectional view showing an example of an organic thin film transistor.

FIG. 1B is a schematic cross-sectional view showing another example of an organic thin film transistor.

FIG. 1C is a schematic cross-sectional view showing a still another example of an organic thin film transistor.

FIG. 1D is a schematic cross-sectional view showing a yet another example of an organic thin film transistor

FIG. 2 is an explanatory graph for the transistor characteristics of an organic thin film transistor of the present invention.

FIG. 3 is an explanatory graph for the relationship between the molecular weight and the field effect mobility of an organic semiconductor material of the present invention.

FIG. 4 is an explanatory graph for the thin film transistor characteristics of the organic thin film transistor of the present invention in a case where V_{ds}=−20V.

FIG. 5 is an explanatory graph for finding the threshold voltage from the thin film transistor characteristics shown in FIG. 4.

### BEST MODE FOR CARRYING OUT THE INVENTION

The organic thin film transistor of the present invention includes a pair of electrodes for allowing a current to flow through an organic semiconductor layer made of an organic semiconductor material, and a third electrode, and further includes an additional component on an as-needed basis.

The organic semiconductor material contains a polymer having a repeating unit expressed by the following general structural formula (I), and the polymer has a weight-average molecular weight (Mw) of 20,000 or more.

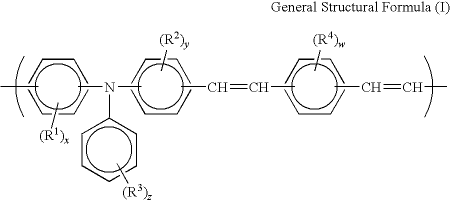

where R¹, R² and R⁴ each independently represents a halogen atom or a group selected from an alkyl group, alkoxy group and alkylthio group all of which may be substituted, R³ represents a halogen atom or a group selected from an alkyl group, alkoxy group, alkylthio group and aryl group all of which may be substituted, z represents an integer of 0 to 5, x, y and w each independently represents an integer of 0 to 4, and when two or more of each of R¹, R², R³ and R⁴ appear, the R's may be the same or different.

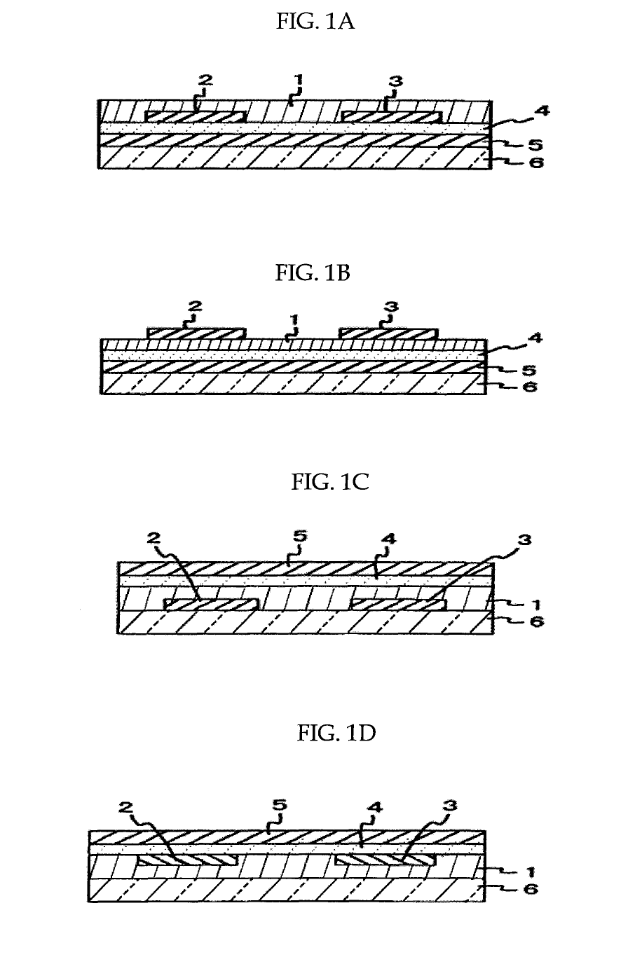

FIGS. 1A to 1B are schematic views each showing an example of an organic thin film transistor to which the present invention is applied.

An organic semiconductor layer 1 formed of organic semiconductor material, which is provided in the organic thin film transistor according to the present invention, is made of a polymer having a repeating unit expressed by the foregoing general structural formula (I), and the polymer has a weight-average molecular weight (Mw) of 20,000 or more. The semiconductor device includes a pair of a source electrode 2 and a drain electrode 3 for allowing a current to flow through the organic semiconductor layer 1, and a gate electrode 5, which is the third electrode. An insulating layer 4 is provided between the gate electrode 5 and the organic semiconductor layer 1. In the organic thin film transistor voltage is applied to the gate electrode 5 and thereby the current flowing between the source electrode 2 and the drain electrode 3 through the organic semiconductor layer 1 is controlled.

The following is a specific example of the polymer repeating unit of the present invention, expressed by the foregoing general structural formula (I). It should be noted that this specific example does not pose any limitation on the present invention.

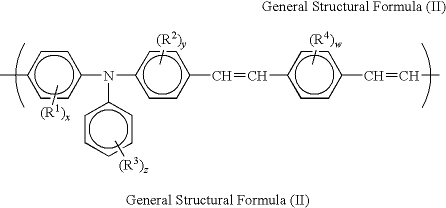

where R¹, R² and R⁴ each independently represents a halogen atom or a group selected from an alkyl group, alkoxy group and alkylthio group all of which may be substituted, R³ represents a halogen atom or a group selected from an alkyl group, alkoxy group, alkylthio group and aryl group all of which may be substituted, z represents an integer of 0 to 5, x, y and w each independently represents an integer of 0 to 4, and when two or more of each of R¹, R², R³ and R⁴ appear, the R's may be the same or different.

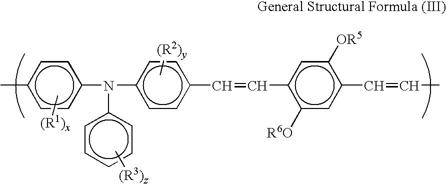

where R¹ and R² each independently represents a halogen atom or a group selected from an alkyl group, alkoxy group and alkylthio group all of which may be substituted, R³ represents a halogen atom or a group selected from an alkyl group, alkoxy group, alkylthio group and aryl group all of which may be substituted, R⁵ and R⁶ represent a straight or branched alkyl group which may be substituted, z represents an integer of 0 to 5, x and y each independently represents an integer of 0 to 4, and when two or more of each of R¹, R² and R³ appear, the R's may be the same or different)

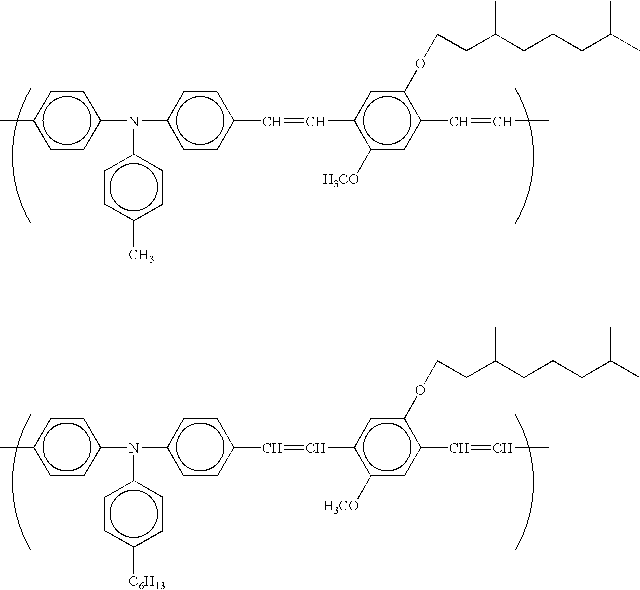

For the production process for polymers containing a repeating unit expressed by the foregoing general structural formula (I), publicly known processes can be used, such as Wittig-Horner reaction using aldehydes and phosphonates, Wittig reaction using aldehydes and phosphonium, Heck reaction using vinyl substitutions and halides, and Ullmann reaction using amines and halides. In particular, Wittig-Horner reaction and Wittig reaction are preferable because of their operability. It should be noted that the details of the production process for the polymers is described in Japanese Patent Application (JP-A) Laid-Open No. 2005-240001.

The polymer expressed by the foregoing general structural formula (I) and has a weight-average molecular weight (Mw) of 20,000 or more has a weight-average molecular weight (Mw) of 20,000 or more, preferably 25,000 or more, more preferably 2,5000 to 500,000, further preferably 25,000 to 200,000, most preferably 25,000 to 150,000 on a polystyrene basis, as determined by gel permeation chromatography (GPC). If the weight-average molecular weight (Mw) is below 20,000, the field effect mobility is reduced. If the weight-average molecular weight (Mw) exceeds 1,000,000, the polymer has low solubility in general solvents and thereby the viscosity of solution in which it is dissolved is increased, making coating processes difficult and causing practical problems, and it is difficult to control the flatness, or planarity, of a film.

The materials used for the organic semiconductor layer of the present invention have excellent solubility in general organic solvents such as dichloromethane, tetrahydrofuran, chloroform, dichlorobenzene and xylene. Thus, it is possible to form a semiconductor thin film by dissolving a high-molecular material of the present invention in a suitable solvent to prepare a solution of suitable concentration and by applying the solution through a wet deposition process.

Examples of the wet deposition process for forming an organic semiconductor layer include spin coating, dipping, blade coating, spray coating, casting, inkjet and printing. Through these publicly known wet deposition technologies, thinner organic semiconductor layers can be obtained. A suitable solvent is selected from the solvent group described above depending on the film deposition process to be used. It should be noted that the organic semiconductor materials according to the present invention are not substantially oxidized even in air if they are solid or dissolved in solution.

The organic thin film transistor will be described with reference to FIG. 1A. FIG. 1A is a cross-sectional view of the organic thin film transistor, and a typical configuration and operation of an organic thin film transistor will be described using this drawing.

Upon application of voltage between a pair of electrodes (or the source electrode 2 and the drain electrode 3) shown in FIG. 1A, a current flows between the source electrode 2 and the drain electrode 3 through the organic semiconductor layer 1. If at this point voltage is applied to the gate electrode 5, which is separated from the organic semiconductor layer 1 by the insulating layer 4, the electric field effect alters carrier conductivity of the organic semiconductor layer 1, whereby the amount of current flowing between the source electrode 2 and the drain electrode 3 can be changed. Reference numeral 6 denotes a substrate, which serves as a gate electrode when a conductive substrate is employed. Likewise, if a conductive substrate is used for the gate electrode 5, the gate electrode 5 also serves as a substrate.

In every structure of the organic thin film transistor of the present invention, the organic semiconductor layer 1 made of the foregoing polymer is so configured that it is sandwiched between the source electrode and drain electrode, as shown in FIGS. 1A to 1B. The thickness of the organic semiconductor layer 1 is so selected that a uniform film—a thin film free of gaps and/or holes that can seriously affect the carrier transportation characteristics of material—can be formed. The thickness of the organic semiconductor layer 1 is preferably 5 nm to 200 nm, more preferably 5 nm to 100 nm, and most preferably 5 nm to 30 nm. If the thickness is below 5 nm, it is likely that the number of induced-carriers is reduced and that the continuity of the formed film is reduced, causing negative effects. If the thickness exceeds 200 nm, the off-current in the resultant transistor increases and thus negative effects occur.

The organic thin film transistor of the present invention is generally formed on the substrate 6 made of glass, silicon or plastic. A plastic substrate is generally used if the resultant device is desired to be flexible, light, or inexpensive. In the transistor structures shown in FIGS. 1A and 1B a conductive substrate is often used because it can also serve as a gate electrode. Incidentally, it may become difficult to form the organic semiconductor layer 1 after forming the insulating layer 4 on the gate electrode 5; if the insulating layer 4 has high surface tension, it may become impossible to form the organic semiconductor layer 1 by, for example, spin coating; and if a organic insulator material is used for insulating layer 4, the solvent used may dissolve the insulating layer 4. In such cases, the insulating layer 4 needs to be formed after forming the organic semiconductor layer 1, as shown in FIGS. 1C and 1D.

The insulating layer 4 is disposed between the gate electrode 5 and the organic semiconductor layer 1. Examples of insulating materials suitable for the insulating layer 4 include inorganic materials such as silicon oxide, silicon nitride, aluminum oxide, aluminum nitride and titanium oxide, and—if the resultant device is desired to be flexible, light, or inexpensive—organic materials including compounds such as polyimides, polyvinyl alcohols, polyvinyl phenols, polyesters, polyethylene, polyphenylenesulfides, polyparaxylylene, polyacrylonitrile and cyanoethylpullulan, and various insulating LB films. These materials may be used in combination.

The formation process for the insulating layer 4 is not particularly limited; for example, any of CVD, plasma CVD, plasma polymerization, vapor deposition, spin coating, dipping, printing, inkjet and Langmuir-Blodgett (LB) method can be used. In addition, if silicon is to be used both as a gate electrode and a substrate, silicon oxide obtained by thermally oxidizing silicon is preferably used.

The organic thin film transistor of the present invention includes three electrodes: the source electrode 2, the drain electrode 3, and the gate electrode 5. The gate electrode 5 is in contact with the insulating layer 4. Each electrode is formed on the substrate 6 by a known conventional technique.

The materials for the source electrode 2, drain electrode 3 and gate electrode 5 are not particularly limited as long as they are conductive materials; examples thereof include platinum, gold, silver, nickel, chrome, copper, iron, tin, antimony, lead, tantalum, indium, aluminum, zinc, magnesium and alloys thereof; conductive metallic oxides such as indium-tin oxide; and inorganic and organic semiconductors, of which conductivity is increased by doping them with conductive substances. For example, single crystal silicon, polysilicon, amorphous silicon, germanium, graphite, polyacetylene, polyparaphenylene, polythiophene, polypyrrol, polyaniline, polythienylenevinylene, and polyparaphenylenevinylene can be cited. Among these conductive materials, those that ohmically connect the source electrode 2 and drain electrode 3 together at a surface where they contact the organic semiconductor layer 1 are preferably used.

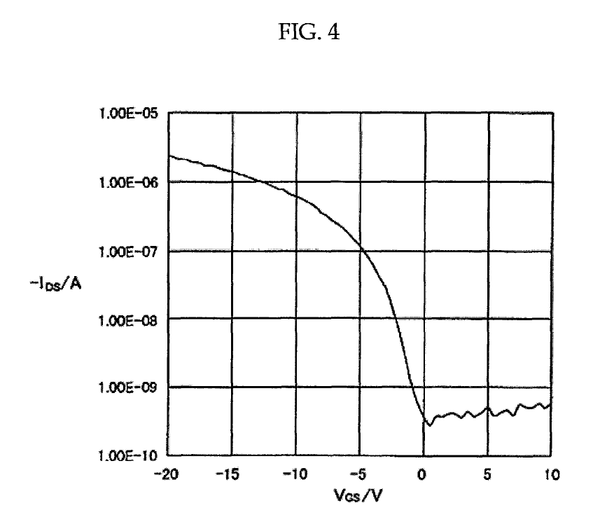

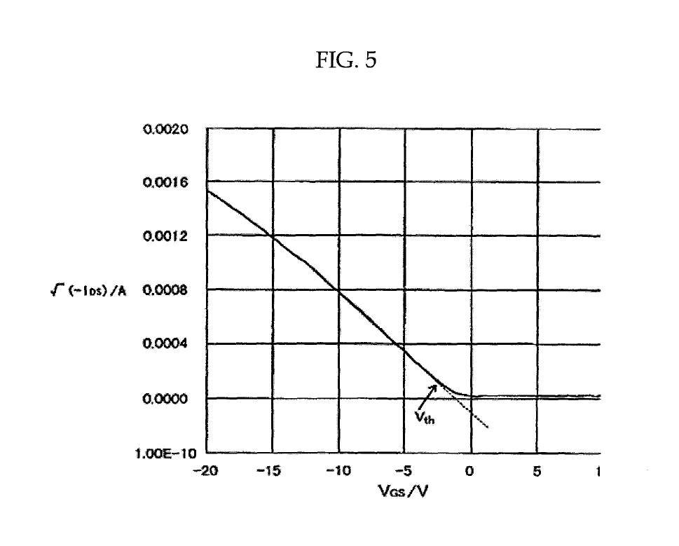

FIGS. 4 and 5 are graphs for transistor performance evaluation. Each graph shows an example of the characteristics of an organic thin film transistor to be described later, where an organic semiconductor material is used as a semiconductor layer (see FIG. 4). The field effect mobility of the organic semiconductor material is calculated using the following equation.

I_{ds}=μCᵢₙW(V_{g}−Vₜₕ)²/2L

(where Cᵢₙ is a capacitance per unit area of a gate insulating film, W is a channel width, L is a channel length, V_{g} is a gate voltage, I_{ds} is a source-drain current, μ is field effect mobility, and Vₜₕ is a gate threshold voltage at which a channel begins to be formed)

To be more specific, −20V is applied between the source and drain, and the source-drain current is measured over the gate voltage range of 10V to −20V. The source-drain current at −20V gate voltage is then substituted into the equation described above, and the square roots of the measured source-drain current values are then plotted against the gate voltage to yield an approximating line. In the approximating curve the gate voltage at which the square root of the source-drain current equals to 0 A is defined as Vₜₕ. Using these values, field effect mobility is calculated (see FIG. 5; note in this drawing that a point of intersection of the broken line and the line corresponding to (−I_{ds})^{1/2}=0.000 is Vₜₕ).

According to the present invention, it is possible to manufacture a field effect transistor with a field effect mobility of 1×10⁻⁴ cm²/Vs or more by adopting the following organic semiconductor material as a semiconductor layer of an organic thin film transistor which includes a pair of electrodes for allowing a current to flow through the organic semiconductor material, and a third electrode, the organic semiconductor material being composed mainly of a polymer which has a repeating unit expressed by the foregoing general structural formula (I) (where R¹, R² and R⁴ each independently represents a halogen atom or a group selected from an alkyl group, alkoxy group and alkylthio group all of which may be substituted, R³ represents a halogen atom or a group selected from an alkyl group, alkoxy group, alkylthio group and aryl group all of which may be substituted, z represents an integer of 0 to 5, x, y and w each independently represents an integer of 0 to 4, and when two or more of each of R¹, R², R³ and R⁴ appear, the R's may be the same or different) and which has a weight-average molecular weight (Mw) of 20,000 or more.

Hereinafter, the present invention will be described in detail based on Examples.

### Synthesis Example 1

A 300-ml, four-necked flask was charged with 1.253 g (3.98 mmol) of dialdehyde, 2.243 g (3.98 mmol) of diphosphonate, and 10.5 mg (0.10 mmol) of benzaldehyde, and the air in the flask was then replaced by nitrogen gas, followed by the addition of 100 ml of tetrahydrofuran. To this resultant solution was added 12 ml of 1.0 mol/dm³ tetrahydrofuran solution of potassium t-butoxide, and stirred for 3 hours at room temperature. Then, 84 μl (0.398 mmol) of diethyl benzylphosphonate was added to the resultant solution and stirred for 2 hours. The reaction was quenched by the addition of about 1 ml of acetic acid. For purification, reprecipitation was then performed by use of dichloromethane and methanol to give 1.674 g of a polymer (total yield=74%).

The elemental analysis value (%) of the polymer was as follows: C, 84.02%; H, 8.22%, N, 2.52% (Calculated value (%): C, 84.12%; H, 7.92%; N, 2.42%).

The weight-average molecular weight (Mw) and number-average molecular weight (Mn) of the polymer on a polystylene basis, as measured by GPC, were 75,000 and 17,000, respectively.

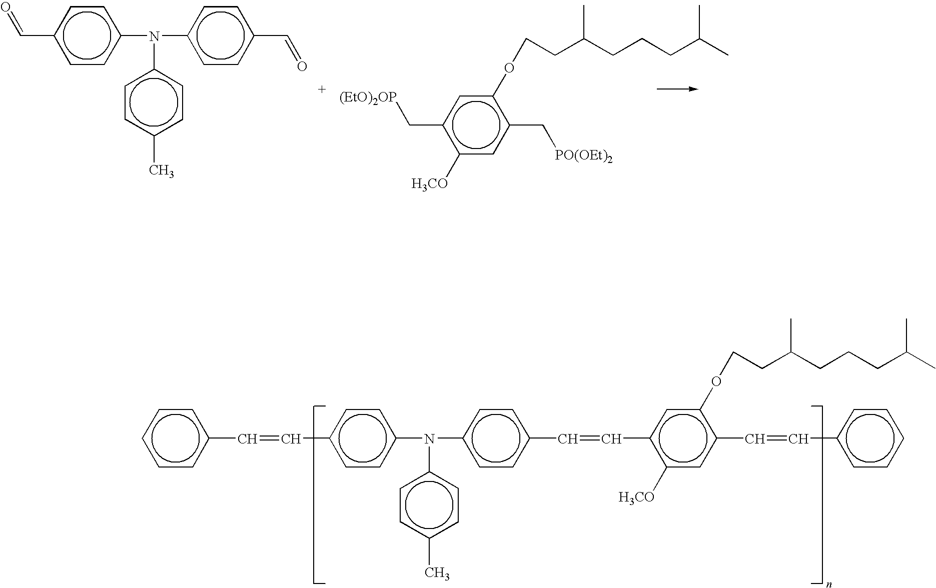

### Synthesis Example 2

A 1000-ml, four-necked flask was charged with 8.48 g (26.9 mmol) of dialdehyde and 15.18 g (26.9 mmol) of diphosphonate, and the air in the flask was then replaced by nitrogen gas, followed by the addition of 800 ml of tetrahydrofuran. To this resultant solution was added 95 ml of 1.0 mol/dm³ tetrahydrofuran solution of potassium t-butoxide, and stirred for 10 minutes at 0° C. Then, 0.614 g (2.69 mmol) of diethyl benzylphosphonate was added to the resultant solution and stirred for 80 minutes. Furthermore, 0.571 g (5.38 mmol) of benzaldehyde was added to this solution and stirred for 2 hours. The reaction was quenched by the addition of about 5 ml of acetic acid. For purification, reprecipitation was then performed by use of tetrahydrofuran and methanol to give a polymer. Reprecipitation was again performed to purify the resultant polymer by use of tetrahydrofuran and acetone to give a polymer with a weight-average molecular weight (Mw) of 123,000.

### Synthesis Example 3

In this Synthesis Example, 13.04 g of a polymer with a weight-average molecular weight (Mw) of 110,000 was produced in a similar manner described in Synthesis Example 2, with the exception that purification using tetrahydrofuran and acetone was omitted (total yield=85%)

### Synthesis Example 4

A 300-ml, four-necked flask was charged with 1.253 g (3.98 mmol) of dialdehyde, 2.243 g (3.98 mmol) of diphosphonate, and 42.2 mg (0.40 mmol) of benzaldehyde, and the air in the flask was then replaced by nitrogen gas, followed by the addition of 100 ml of tetrahydrofuran. To this resultant solution was added 12 ml of 1.0 mol/dm³ tetrahydrofuran solution of potassium t-butoxide, and stirred for 3 hours at room temperature. Then, 84 μl (0.398 mmol) of diethyl benzylphosphonate was added to the resultant solution and stirred for 2 hours. The reaction was quenched by the addition of acetic acid. For purification, reprecipitation was then performed by use of dichloromethane and methanol to give 1.377 g of a polymer with a weight-average molecular weight (Mw) of 25,000 (total yield=60%).

### Synthesis Example 5

A 300-ml, four-necked flask was charged with 0.8515 g (2.70 mmol) of dialdehyde and 1.5246 g (2.70 mmol) of diphosphonate, and the air in the flask was then replaced by nitrogen gas, followed by the addition of 75 ml of tetrahydrofuran. To this resultant solution was added 7 ml of 1.0 mol/dm³ tetrahydrofuran solution of potassium t-butoxide, and stirred for 19 hours at room temperature. Then, 131.6 mg (0.576 mmol) of diethyl benzylphosphonate was added to the resultant solution and stirred for 2.5 hours. Furthermore, 114.6 mg (1.08 mmol) of benzaldehyde was added to this solution and stirred for 2 hours. The reaction was quenched by the addition of about 1 ml of acetic acid. For purification, reprecipitation was then performed by use of tetrahydrofuran and methanol to give 1.07 g of a polymer with a weight-average molecular weight (Mw) of 20,000 (total yield=70%).

### Synthesis Example 6

A 300-ml, four-necked flask was charged with 0.8454 g (2.68 mmol) of dialdehyde and 1.5136 g (2.68 mmol) of diphosphonate, and the air in the flask was then replaced by nitrogen gas, followed by the addition of 60 ml of tetrahydrofuran. To this resultant solution was added 1.3 g of 28% methanol solution of sodium methoxide, and stirred for 19 hours at room temperature. Then, 130.7 mg (0.572 mmol) of diethyl benzylphosphonate was added to the resultant solution and stirred for 2 hours. Furthermore, 113.8 mg (1.07 mmol) of benzaldehyde was added to this solution and stirred for 2 hours. The reaction was quenched by the addition of about 1 ml of acetic acid. For purification, reprecipitation was then performed by use of tetrahydrofuran and methanol to give 0.944 g of a polymer with a weight-average molecular weight (Mw) of 4,400 (total yield=62%).

### Synthesis Example 7

A 300-ml, four-necked flask was charged with 1.250 g (3.97 mmol) of dialdehyde, 2.231 g (3.97 mmol) of diphosphonate, and 63.2 mg (0.59 mmol) of benzaldehyde, and the air in the flask was then replaced by nitrogen gas, followed by the addition of 100 ml of tetrahydrofuran. To this resultant solution was added 12 ml of 1.0 mol/dm³ tetrahydrofuran solution of potassium t-butoxide, and stirred for 3 hours at room temperature. Then, 84 μl (0.398 mmol) of diethyl benzylphosphonate was added to the resultant solution and stirred for 2 hours. The reaction was quenched by the addition of acetic acid. For purification, reprecipitation was then performed by use of tetrahydrofuran and methanol to give a polymer with a weight-average molecular weight (Mw) of 15,000.

### Example 1

The polymer prepared in Synthesis Example 2 having a weight-average molecular weight (Mw) of 123,000 was used to prepare an organic thin film transistor having a structure shown in FIG. 1B. The p-doped silicon substrate that serves as a gate electrode was thermally oxidized to form a SiO₂ insulating layer of 100 nm thickness. Thereafter, the oxide film thus formed was removed from one surface of the substrate and Al was deposited thereon. Next, the SiO₂ insulating layer was treated with hexamethyldisilaxane, and an approximately 1.0 wt % THF/p-xylene (THF/p-xylene=80:20) solution of the polymer produced in the Synthesis Example 1 and has a weight-average molecular weight (Mw) of 123,000 was applied on the substrate by spin coating, followed by drying. In this way an organic semiconductor layer of 30 nm thickness was formed. Au was then deposited on the organic semiconductor layer as a source-drain electrode with a channel length of 30 μm and a channel width of 10 mm.

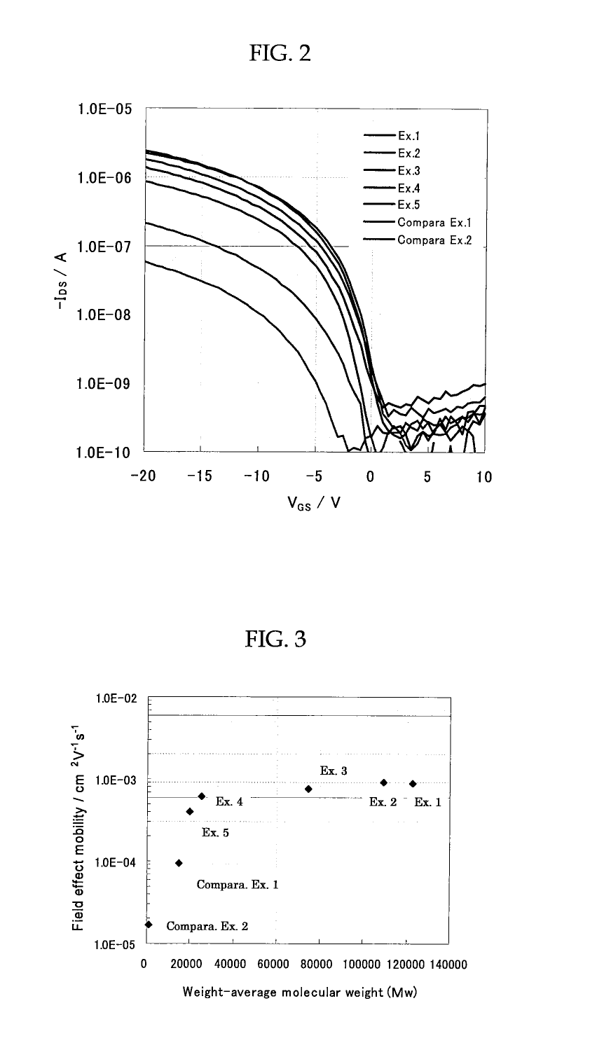

FIG. 2 is a graph for the transistor characteristics of the organic thin film transistor prepared through the foregoing process. As can be seen from FIG. 2, the prepared device showed excellent transistor characteristics.

In addition, the field effect mobility of the organic semiconductor was calculated using the following equation.

I_{ds}=μCᵢₙW(V_{g}−Vₜₕ)²/2L

(where Cᵢₙ is a capacitance per unit area of a gate insulating film, W is a channel width, L is a channel length, V_{g} is a gate voltage, I_{ds} is a source-drain current, μ is field effect mobility, and Vₜₕ is a gate threshold voltage at which a channel begins to be formed)

The on-current and field effect mobility of the thin film transistor thus prepared were −2.28 μA and 8.8×10⁻⁴ cm²/Vs, respectively.

Moreover, the on/off ratio—the ratio of the I_{ds} value observed at V_{ds}=−20V and V_{g}=−20V to the minimum I_{ds} value observed in the V_{g} range of +10V to −20V—was 2.4×10³, and the threshold voltage was −0.28V. Thus, the prepared organic thin film transistor showed excellent transistor characteristics.

### Example 2

An organic thin film transistor having the structure shown in FIG. 1B was prepared in accordance with the procedure described in Example 1, with the exception that the polymer prepared in Synthesis Example 3 having a weight-average molecular weight (Mw) of 110,000 was used. The prepared organic thin film transistor showed excellent transistor characteristics.

The on-current, threshold voltage, field effect mobility and on/off ratio of the prepared thin film transistor were −2.35 μA, 0.25V, 9.20×10⁻⁴ cm²/Vs and 3.3×10³, respectively.

### Example 3

An organic thin film transistor having the structure shown in FIG. 1B was prepared in accordance with the procedure described in Example 1, with the exception that the polymer prepared in Synthesis Example 1 having a weight-average molecular weight (Mw) of 75,000 was used. The prepared organic thin film transistor showed excellent transistor characteristics.

The on-current, threshold voltage, field effect mobility and on/off ratio of the prepared thin film transistor were −1.72 μA, −0.53V, 7.49×10⁻⁴ cm²/Vs and 2.8×10³, respectively. The obtained results are shown in FIG. 2.

### Example 4

An organic thin film transistor having the structure shown in FIG. 1B was prepared in accordance with the procedure described in Example 1, with the exception that the polymer prepared in Synthesis Example 4 having a weight-average molecular weight (Mw) of 25,000 was used. The prepared organic thin film transistor showed excellent transistor characteristics.

The on-current, threshold voltage, field effect mobility and on/off ratio of the prepared thin film transistor were −1.45 μA, −0.35V, 6.19×10⁻⁴ cm²/Vs and 2.5×10³, respectively. The obtained results are shown in FIG. 2.

### Example 5

An organic thin film transistor having the structure shown in FIG. 1B was prepared in accordance with the procedure described in Example 1, with the exception that the polymer prepared in Synthesis Example 5 having a weight-average molecular weight (Mw) of 20,000 was used. The prepared organic thin film transistor showed excellent transistor characteristics.

The on-current, threshold voltage, field effect mobility and on/off ratio of the prepared thin film transistor were −0.89 μA, −0.73V, 4.04×10⁻⁴ cm²/Vs and 5.0×10³, respectively. The obtained results are shown in FIG. 2.

### Comparative Example 1

A film transistor having the structure shown in FIG. 1B was prepared in accordance with the procedure described in Example 1, with the exception that the polymer prepared in Synthesis Example 6 having a weight-average molecular weight (Mw) of 4,400 was used. The prepared organic thin film transistor showed excellent transistor characteristics but had low field effect mobility (see FIG. 2).

The on-current, threshold voltage, field effect mobility and on/off ratio of the prepared thin film transistor were −0.078=A, −2.13V, 3.52×10⁻⁵ cm²/Vs and 1.6×10³, respectively. FIG. 3 illustrates the relationship between the weight-average molecular weight and field effect mobility.

### Comparative Example 2

A film transistor having the structure shown in FIG. 1B was prepared in accordance with the procedure described in Example 1, with the exception that the polymer prepared in Synthesis Example 7 having a weight-average molecular weight (Mw) of 15,000 was used. The prepared organic thin film transistor showed excellent transistor characteristics but had low field effect mobility.

The on-current, threshold voltage, field effect mobility and on/off ratio of the prepared thin film transistor were −0.22 μA, −0.99V, 9.45×10⁻⁵ (cm²/Vs), and 2.8×10³, respectively.

As can be seen from FIG. 3, the samples prepared in Examples 1 to 5, all of which have a weight-average molecular weight (Mw) of 20,000 or more, had better field effect mobility than the samples prepared in Comparative Examples 1 and 2, the weight-average molecular weights (Mw) of which are 4,400 and 15,000, respectively. In addition, it was observed that the field effect mobility tends to increase as the weight-average molecular weight (Mw) increases. From Examples it can be seen that polymers with weight-average molecular weights (Mw) of 20,000 or more are preferable.

### INDUSTRIAL APPLICABILITY

The organic thin film transistor of the present invention can be suitably used as a switching device for displays such as liquid crystal displays, electrophoretic displays and organic EL displays, because using the organic thin film transistor it is possible manufacture large-area devices at low costs and because it has high field effect mobility.

1. A method for producing an organic thin film transistor, the method comprising;
treating a SiO₂ insulating layer with hexamethyldisilazane,
wherein the organic thin film transistor comprises a pair of electrodes for allowing a current to flow through an organic semiconductor layer made of an organic semiconductor material and a third electrode,
wherein the organic semiconductor material comprises a polymer having a repeating unit expressed by the following general structural formula (I), and the polymer has a weight-average molecular weight (Mw) of 20,000 or more, and 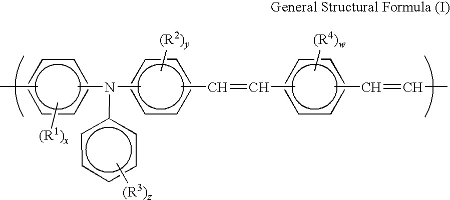
where R¹, R², and R⁴ each independently represents a halogen atom or a group selected from an alkyl group, alkoxy group and alkylthio group all of which may be substituted; R³ represents a halogen atom or a group selected from an alkyl group, alkoxy group, alkylthio group, and aryl group all of which may be substituted; z represents an integer of 0 to 5; x, y, and w each independently represents an integer of 0 to 4; and when two or more of each of R¹, R², R³ and R⁴ appear, the R's may be the same or different.

2. The method according to claim 1, wherein the third electrode is a gate electrode, and an insulating layer is provided between the gate electrode and the organic semiconductor layer.

3. The method according to claim 1, wherein the organic semiconductor layer has a thickness of from 5 nm to 200 nm.

4. The method according to claim 1, wherein the organic semiconductor layer has a thickness of from 5 nm to 100 nm.

5. The method according to claim 1, wherein the organic semiconductor layer has a thickness of from 5 nm to 30 nm.

6. The method according to claim 2, wherein the insulating layer is formed of an insulating material selected from the group consisting of silicon oxide, silicon nitride, aluminum oxide, aluminum nitride, titanium oxide, polyimides, polyvinyl alcohols, polyvinyl phenols, polyesters, polyethylene, polyphenylenesulfides, polyparaxylylene, polyacrylonitrile, cyanoethylpullulan, and combinations thereof.
